(19) United States
(12) Patent Application Publication
(10) Pub. No.: US 2026/0063725 A1
(43) Pub. Date: Mar. 5, 2026

(54) DETECTION SYSTEM OF STATE OF CHARGE OF FLOW BATTERY

(71) Applicant: ShenEnergy Tech Ltd., Tainan City (TW)

(72) Inventors: Sheng-Yu WANG, Hsinchu County (TW); Yao-Ming WANG, Kaohsiung City (TW); Pin-Xian LIN, Chiayi City (TW); Shang-Ching CHUANG, Kaohsiung City (TW); Ma-Li CHANG, New Taipei City (TW)

(73) Assignee: ShenEnergy Tech Ltd., Tainan City (TW)

(21) Appl. No.: 18/825,181

(22) Filed: Sep. 5, 2024

(51) Int. Cl. G01R 31/388; G01N 21/3577; H01M 8/04082; H01M 8/18

(52) U.S. Cl. CPC G01R 31/388; G01N 21/3577; H01M 8/04216; H01M 8/188

(57) ABSTRACT

A detection system of a state of charge of a flow battery is adapted to detect the state of charge (SoC) of the flow battery. The flow battery includes a negative electrode circulation pipeline adapted to circularly transport a negative electrode electrolyte between a negative electrode and a negative electrode electrolyte storage tank. The detection system of the state of charge of the flow battery includes a transparent pipe communicating with the negative electrode circulation pipeline and a detection device including a light source and a receiver. The light source and the receiver are respectively disposed on two opposite sides of the transparent pipe in a radial direction of the transparent pipe. The light source emits a light with a single wavelength. After the light passes through the negative electrode electrolyte in the transparent pipe, the receiver receives the light and outputs a signal.

### BACKGROUND OF THE INVENTION

### Technical Field

The present invention relates generally to a flow battery, and more particularly to a system, which could detect a state of charge of a flow battery.

### Description of Related Art

It's known that a speed of consuming fossil energy is gradually increased with the rapid development of the industry, thereby causing a great shortage of the fossil energy and a gradual deterioration of the environment. Therefore, developing renewable energy sources to replace the fossil energy has been a significant developmental tendency. Currently, energy storage technologies of the renewable energy contain a redox flow battery (RFB) and “redox flow battery” is abbreviated to “flow battery” hereafter. The flow battery could provide a usage of charging and discharging circularly and could effectively maintain a voltage, so that the renewable energy source could stably supply a power.

A structure of a conventional flow battery typically includes two battery units and an exchange membrane, wherein the exchange membrane is disposed between the two battery units. The two battery units are respectively connected to a positive electrode electrolyte container and a negative electrode electrolyte container. A positive electrode electrolyte in the positive electrode electrolyte container and a negative electrode electrolyte in the negative electrode electrolyte container are respectively pumped by two pump components into each of the two battery units to execute an electrochemical reaction to generate an electrical power. A conventional way to monitor a state of charge (SoC) of the flow battery is to take out the electrolyte from the flow battery and dilute the electrolyte before performing detection. Such monitoring way causing damages to the structure of the flow battery and includes a complicated detection procedure. Therefore, how to provide an easy and convenient detection system of a state of charge of a flow battery is a problem needed to be solved.

### BRIEF SUMMARY OF THE INVENTION

In view of the above, the primary objective of the present invention is to provide a detection system of a state of charge of a flow battery, which could monitor a real-time state of charge of the flow battery without taking out an electrolyte from the flow battery.

The present invention provides a detection system of a state of charge of a flow battery adapted to detect the state of charge (SoC) of the flow battery, wherein the flow battery includes a negative electrode circulation pipeline. The negative electrode circulation pipeline is adapted to circularly transport a negative electrode electrolyte between a negative electrode and a negative electrode electrolyte storage tank. The detection system of the state of charge of the flow battery includes a transparent pipe and a detection device, wherein the transparent pipe communicates with the negative electrode circulation pipeline. The detection device includes a light source and a receiver, wherein the light source and the receiver are respectively disposed on two opposite sides of the transparent pipe in a radial direction of the transparent pipe. The light source emits a light with a single wavelength. After the light passes through the negative electrode electrolyte in the transparent pipe, the receiver receives the light and outputs a signal.

With the aforementioned design, through the transparent pipe and the negative electrode circulation pipeline, the negative electrode electrolyte could be directly detected without being taken out from the flow battery for detection; the state of charge of the flow battery could be obtained through the signal. In this way, a purpose of providing the easy and convenient detection system of the state of charge of the flow battery could be achieved.

### BRIEF DESCRIPTION OF THE SEVERAL VIEWS OF THE DRAWINGS

The present invention will be best understood by referring to the following detailed description of some illustrative embodiments in conjunction with the accompanying drawings, in which

FIG. 1 is a schematic view of the detection system of the state of charge of the flow battery and the flow battery according to an embodiment of the present invention;

FIG. 2 is a perspective view of the detection system of the state of charge of the flow battery according to the embodiment of the present invention;

FIG. 3 is a schematic view of a part of the detection system of the state of charge of the flow battery according to the embodiment of the present invention;

FIG. 4 is a side view of the detection system of the state of charge of the flow battery according to the embodiment of the present invention, wherein the cover is represented with an imaginary line;

FIG. 5 is a top view of the detection system of the state of charge of the flow battery according to the embodiment of the present invention, wherein the cover is not shown;

FIG. 6 is a flow chart of a detection method of the state of charge of the flow battery according to another embodiment of the present invention;

FIG. 7 is a schematic view, showing a detected voltage, a voltage, and a current change with a time according to the another embodiment of the present invention;

FIG. 8 is a schematic view showing the detected voltage and values of the state of charge according to the another embodiment of the present invention; and

FIG. 9 is a schematic view showing the detected voltage corresponding to different resistances of the current-limiting resistor and the values of the state of charge according to the another embodiment of the present invention.

### DETAILED DESCRIPTION OF THE INVENTION

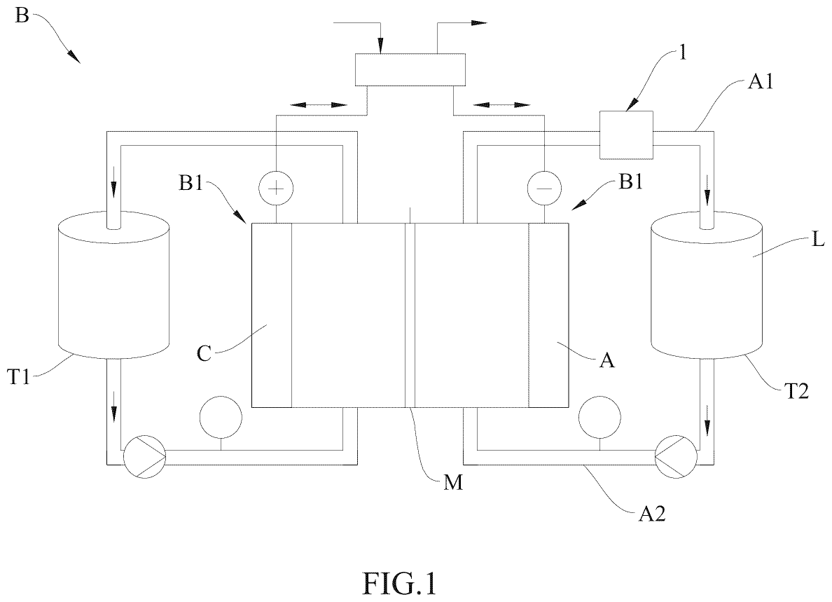

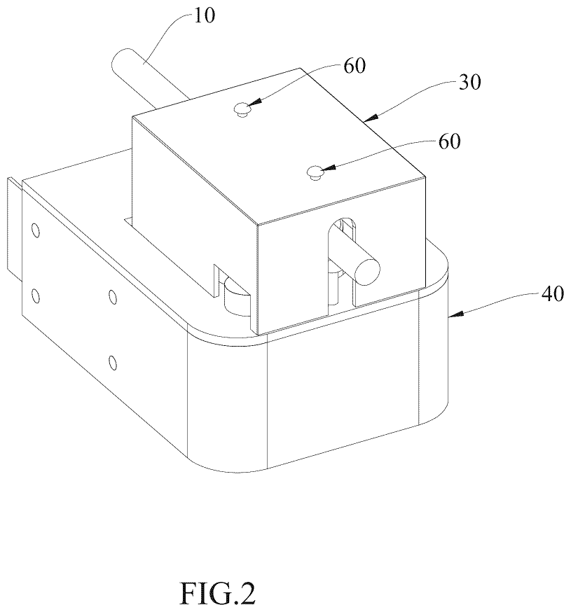

A detection system 1 of a state of charge of a flow battery according to an embodiment of the present invention is illustrated in FIG. 1 to FIG. 5 and is adapted to detect the state of charge (SoC) of the flow battery B. The flow battery B includes two battery units B1 and an exchange membrane M, wherein the exchange membrane M is disposed between the two battery units B1. Each of the two battery units B1 includes a positive electrode C and a negative electrode A. The two battery units are respectively connected to a positive electrode electrolyte storage tank T1 and a negative electrode electrolyte storage tank T2. A positive electrode electrolyte in the positive electrode electrolyte storage tank T1 is pumped by a pump into one of the two battery units B1 and a negative electrode electrolyte L in the negative electrode electrolyte storage tank T2 is pumped by another pump into the other battery unit B1, thereby executing an electrochemical reaction to generate an electrical power.

The flow battery B further includes a positive electrode circulation pipeline and a negative electrode circulation pipeline, wherein the positive electrode circulation pipeline is adapted to circularly transport the positive electrode electrolyte between the positive electrode C and the positive electrode electrolyte storage tank T1. The negative electrode circulation pipeline is adapted to circularly transport the negative electrode electrolyte L between the negative electrode A and the negative electrode electrolyte storage tank T2.

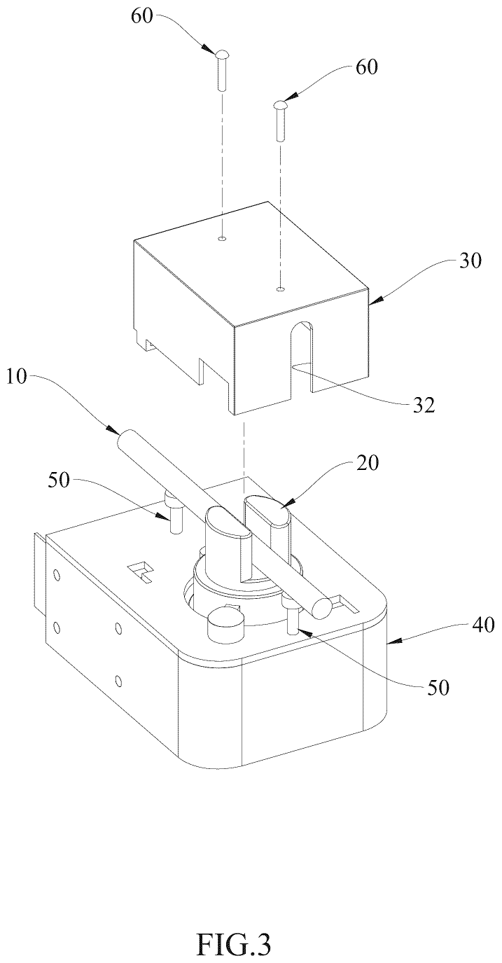

Referring to FIG. 1 and FIG. 3, the detection system 1 of the state of charge of the flow battery includes a transparent pipe 10 and a detection device 20, wherein the transparent pipe 10 communicates with the negative electrode circulation pipeline. For example, the negative electrode circulation pipeline includes a negative electrode exit pipe A1 and a negative electrode entrance pipe A2, wherein the negative electrode exit pipe A1 is adapted to output the negative electrode electrolyte L on the negative electrode A to the negative electrode electrolyte storage tank T2. The negative electrode entrance pipe A2 is adapted to input the negative electrode electrolyte L in the negative electrode electrolyte storage tank T2 to the negative electrode A. In the current embodiment, the transparent pipe 10 and the detection device 20 are disposed on the negative electrode exit pipe A1; the transparent pipe 10 communicates with the negative electrode exit pipe A1, so that the negative electrode electrolyte L outputted from the negative electrode A to the negative electrode electrolyte storage tank T2 could pass through the transparent pipe 10.

In other embodiments, the transparent pipe 10 and the detection device 20 could be disposed on the negative electrode entrance pipe A2; the transparent pipe 10 communicates with the negative electrode entrance pipe A2.

More specifically, the transparent pipe 10 is a glass pipe and an outer diameter D of the transparent pipe 10 is between 5.4 mm and 6.6 mm. Preferably, the outer diameter D of the transparent pipe 10 is 6 mm. In practice, the transparent pipe 10 could be a pipe made of any transparent material. For example, the transparent pipe 10 could be a pipe made of any transparent material which does not absorb a light with a wavelength between 750 nm and 1100 nm. In addition, the outer diameter D of the transparent pipe 10 could be, but not limited to, less than 5.4 mm or greater than 6.6 mm.

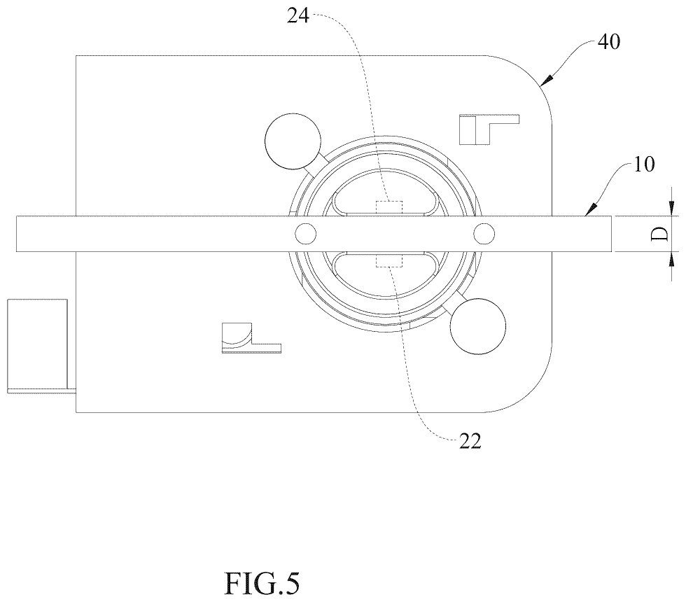

Referring to FIG. 5, the detection device 20 includes a light source 22 and a receiver 24, wherein the light source 22 and the receiver 24 are respectively disposed on two opposite sides of the transparent pipe 10 in a radial direction of the transparent pipe 10 and are respectively in contact with the two opposite sides of the transparent pipe 10. The light source 22 emits a light with a single wavelength. After the light passes through the transparent pipe 10 and the negative electrode electrolyte L in the transparent pipe 10, the receiver 24 receives the light and outputs a signal, thereby obtaining the state of charge of the flow battery B through the signal.

In the current embodiment, the light source 22 and the receiver 24 are disposed in an outer portion of the transparent pipe 10 as an example. In practice, at least one of the light source 22 and the receiver 24 could be disposed in an inner portion of the transparent pipe 10. For example, the light source 22 could be disposed in the outer portion of the transparent pipe 10 and the receiver 24 could be disposed in the inner portion of the transparent pipe 10; alternatively, the receiver 24 could be disposed in the outer portion of the transparent pipe 10 and the light source 22 could be disposed in the inner portion of the transparent pipe 10; alternatively, the light source 22 and the transparent pipe 10 could be both disposed in the inner portion of the transparent pipe 10. Preferably, when the receiver 24 is disposed in the inner portion of the transparent pipe 10, the receiver 24 is covered by a transparent and waterproof material and is disposed in the transparent and waterproof material, so that the light of the light source 22 could pass through the transparent and waterproof material to be received by the receiver 24 and the negative electrode electrolyte L in the transparent pipe 10 could be prevented from being directly in contact with the receiver 24 and damaging the receiver 24.

The detection device 20 is a transmittance meter, wherein the transmittance meter includes the light source 22 and the receiver 24. The signal outputted by the transmittance meter is a voltage signal. The light source 22 could be a LED light source or a laser light source. The single wavelength of the light is between 750 nm and 1100 nm. Preferably, the single wavelength of the light is 850 nm. More specifically, the detection device 20 includes a current-limiting resistor electrically connected to the light source 22, thereby adjusting a resistance of the current-limiting resistor to modulate a luminous intensity of the light source 22.

More specifically, referring to FIG. 3 to FIG. 5, the detection system 1 of the state of charge of the flow battery includes a cover 30, a base 40, two first positioning members 50, and two second positioning members 60. The light source 22 and the receiver 24 are disposed on a top portion of the base 40. The cover 30 is made of opaque materials, is disposed on the top portion of the base 40, and forms a receiving space with the top portion of the base 40. A part of the transparent pipe 10 is disposed in the receiving space. The cover 30 is detachably connected to the top portion of the base 40.

Two openings 32 are respectively provided on two opposite sides of the cover 30. The transparent pipe 10 passes through the two openings 32 of the two opposite sides of the cover 30, so that two ends of the transparent pipe 10 could pass through the cover 30 to communicate with the negative electrode exit pipe A1 and a light of an external space could be blocked by the cover 30 from entering the receiving space which interferes a detection result of the detection device 20, thereby achieving an effect of enhancing a detection accuracy of the detection device 20.

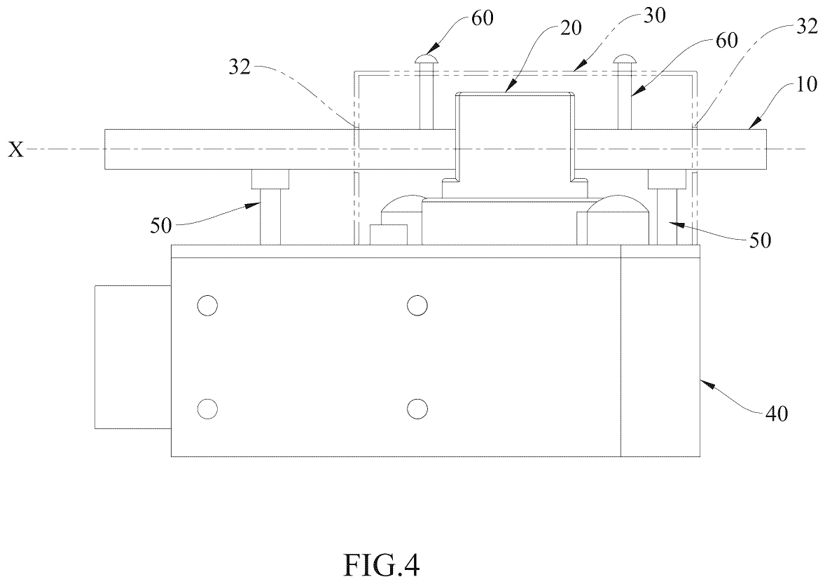

Referring to FIG. 4, an axis X is defined. The transparent pipe 10 extends along the axis X. The two first positioning members 50 are disposed on the top portion of the base 40. The light source 22 and the receiver 24 are disposed between the two first positioning members 50 along the axis X. The transparent pipe 10 is disposed on a top portion of each of the two first positioning members 50. The two second positioning members 60 are disposed between the two first positioning members 50 along the axis X. The two second positioning members 60 are connected to the cover 30 and a bottom of each of the two second positioning members 60 abuts against an outer wall of the transparent pipe 10. Through the disposition of the two first positioning members 50 and the two second positioning members 60, the transparent pipe 10 could be firmly disposed on the base 40.

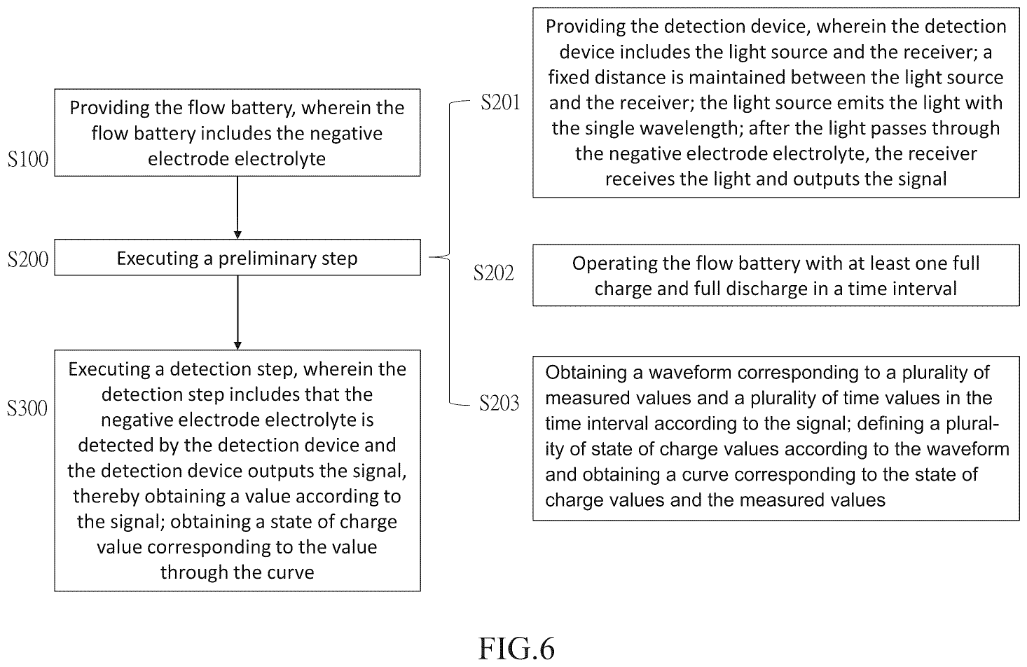

FIG. 6 is a flow chart of a detection method of the state of charge of the flow battery according to another embodiment of the present invention. In the current embodiment, the detection method of the state of charge of the flow battery is executed by the detection system 1 of the state of charge of the flow battery as an example. In other embodiments, the detection method of the state of charge of the flow battery could be executed by other devices.

The detection method of the state of charge of the flow battery includes:

Step S100: the flow battery B is provided, wherein the flow battery B includes the negative electrode electrolyte L.

Step S200: a preliminary step is executed, wherein the preliminary step includes:

Step S201: the detection device 20 is provided, wherein the detection device 20 includes the light source 22 and the receiver 24; a fixed distance is maintained between the light source 22 and the receiver 24; the fixed distance is preferably 6 mm; the light source 22 emits the light with the single wavelength; after the light passes through the negative electrode electrolyte L, the receiver 24 receives the light and outputs the signal. The signal is a detected voltage and is an analog signal as an example. In other embodiments, the signal could be a digital signal converted from the analog signal. The single wavelength of the light is between 750 nm and 1100 nm. Preferably, the single wavelength of the light is 850 nm. The flow battery B includes the negative electrode exit pipe A1 outputting the negative electrode electrolyte L from the negative electrode A to the negative electrode electrolyte storage tank T2. The detection device 20 detects the negative electrode electrolyte L in the negative electrode exit pipe A1. More specifically, in the current embodiment, the light source 22 of the detection device 20 and the receiver 24 of the detection device 20 are disposed on the negative electrode exit pipe A1 to detect the negative electrode electrolyte L in the transparent pipe 10. In other embodiments, the light source 22 of the detection device 20 and the receiver 24 of the detection device 20 could be disposed on the negative electrode electrolyte storage tank T2 or on the negative electrode entrance pipe A2 to detect the negative electrode electrolyte L.

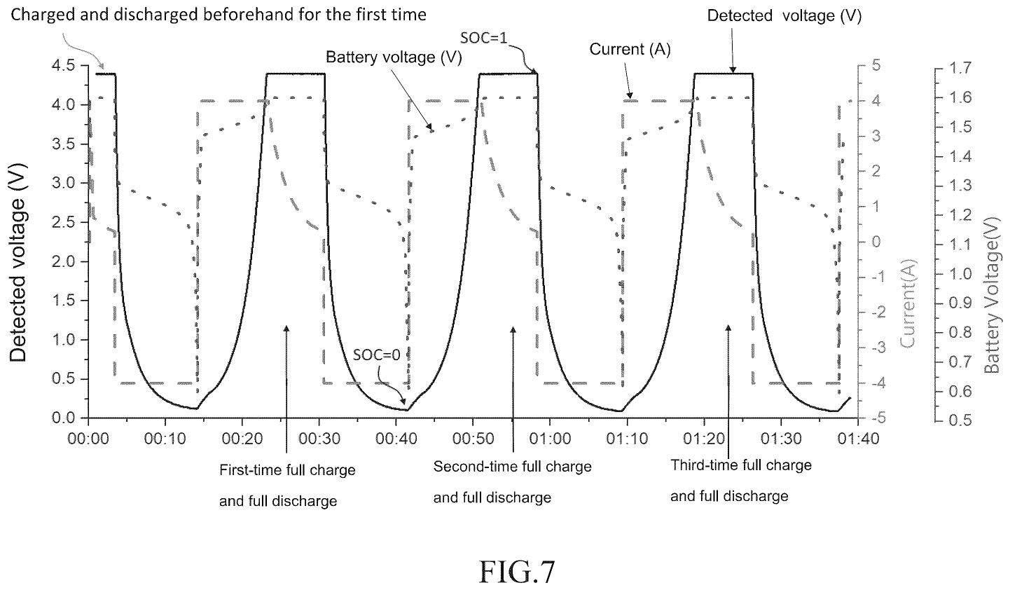

Step S202: the flow battery B is operated with at least one full charge and full discharge in a time interval. Preferably, before the flow battery B is operated with at least one full charge and full discharge, the flow battery B is charged and discharged once beforehand. The at least one full charge and full discharge contains a charge in a constant current mode and a charge/discharge in a constant voltage mode. A current density of the at least one full charge and full discharge is 40 mA/cm². FIG. 7 is a schematic view showing the detected voltage, a voltage, and a current of the three-times full charge and full discharge after the flow battery B is charged and discharged once beforehand for the first time according to the current embodiment of the present invention. In other embodiments, due to a conversion efficiency of a battery system, a charge-discharge cycle test with the current density less than or greater than 40 mA/cm² could be executed.

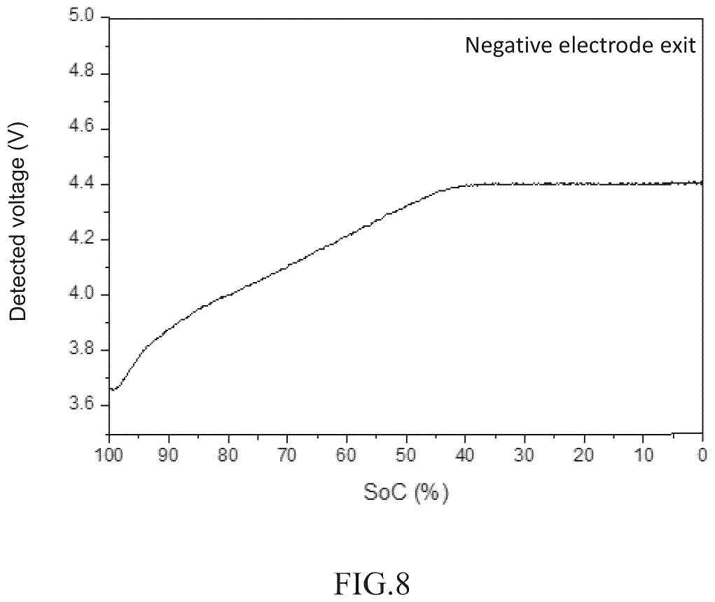

Step S203: a waveform corresponding to a plurality of measured values and a plurality of time values in the time interval are obtained according to the signal, i.e., the waveform corresponding to the plurality of voltages and the plurality of time values; a plurality of state of charge (SoC) values (as shown in FIG. 7) are defined according to the waveform and a curve (as shown in FIG. 8) corresponding to the measured values and the state of charge values is obtained. The measured values are the values of the detected voltage outputted by the receiver 24.

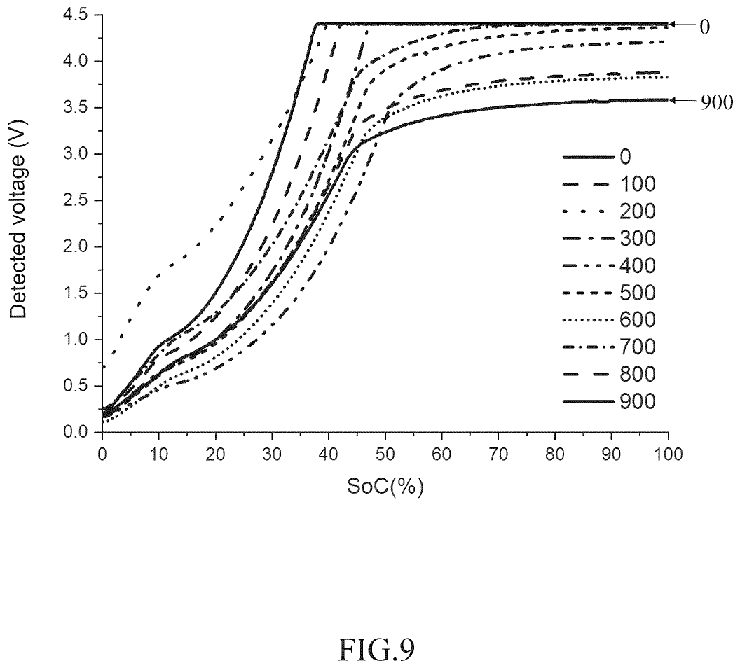

The preliminary step includes adjusting the luminous intensity of the light source 22, so that a slope of any part of the curve is not equal to 0 and is not infinite. Through adjusting the resistance of the current-limiting resistor, the luminous intensity of the light source 22 could be modulated. Referring to FIG. 9, corresponding to different resistances of the current-limiting resistor (i.e., 0, 100, 200, . . . , 900 Ω), a plurality of curves corresponding to the detected voltages and the state of charge values could be obtained. When the resistance of the current-limiting resistor is 0 Ω, 100 Ω, 200 Ω, or 300 Ω, the slope of the curve with the state of charge value greater than 60% is 0, thereby causing a problem that a change of the state of charge could not be determined. When the resistance of the current-limiting resistor is 600 Ω, 700 Ω, 800 Ω, or 900 Ω, the slop of the curve changes slightly, thereby causing a problem that a resolution for determining the change of the state of charge is low, so that the change of the state of charge could not be easily determined. In the current embodiment, the positive electrode electrolyte is detected as an example and the detection result of the positive electrode electrolyte could be applied to the negative electrode electrolyte. Referring to FIG. 9, when the resistance of the current-limiting resistor is 400 Ω or 500 Ω, the slope of the curve changes obviously, so that the resolution for determining the change of the state of charge could be better.

Step: S300: a detection step is executed, wherein the detection step includes that the negative electrode electrolyte L is detected by the detection device 20 and the detection device 20 outputs the signal, thereby obtaining a value according to the signal; through the curve as shown in FIG. 9, the state of charge value corresponding to the value could be obtained. In other words, the value of the detected voltage could be obtained through the signal; then the value of the detected voltage is compared with a schematic view showing the values of the detected voltage and the state of charge values obtained after step S100 and step S200 are executed, thereby obtaining the corresponding state of charge value.

With the aforementioned design, the negative electrode electrolyte could be directly detected and the state of charge of the flow battery could be obtained through the signal, thereby achieving a purpose of providing the easy and convenient detection system of the state of charge of the flow battery.

It must be pointed out that the embodiments described above are only some preferred embodiments of the present invention. All equivalent structures which employ the concepts disclosed in this specification and the appended claims should fall within the scope of the present invention.

What is claimed is:

1. A detection system of a state of charge of a flow battery adapted to detect the state of charge (SoC) of the flow battery, wherein the flow battery comprises a negative electrode circulation pipeline; the negative electrode circulation pipeline is adapted to circularly transport a negative electrode electrolyte between a negative electrode and a negative electrode electrolyte storage tank; the detection system of the state of charge of the flow battery comprises:
a transparent pipe communicating with the negative electrode circulation pipeline; and
a detection device comprising a light source and a receiver, wherein the light source and the receiver are respectively disposed on two opposite sides of the transparent pipe in a radial direction of the transparent pipe; the light source emits a light with a single wavelength; after the light passes through the negative electrode electrolyte in the transparent pipe, the receiver receives the light and outputs a signal.

2. The detection system of the state of charge of the flow battery as claimed in claim 1, wherein an outer diameter of the transparent pipe is between 5.4 mm and 6.6 mm.

3. The detection system of the state of charge of the flow battery as claimed in claim 2, wherein the outer diameter of the transparent pipe is 6 mm.

4. The detection system of the state of charge of the flow battery as claimed in claim 1, wherein the single wavelength of the light is between 750 nm and 1100 nm.

5. The detection system of the state of charge of the flow battery as claimed in claim 4, wherein the single wavelength of the light is 850 nm.

6. The detection system of the state of charge of the flow battery as claimed in claim 1, wherein the detection device comprises a current-limiting resistor; the current-limiting resistor is electrically connected to the light source.

7. The detection system of the state of charge of the flow battery as claimed in claim 1, wherein the transparent pipe is a glass pipe or a pipe made of any transparent material which does not absorb a light with a wavelength between 750 nm and 1100 nm.

8. The detection system of the state of charge of the flow battery as claimed in claim 1, further comprising a cover, wherein two openings are respectively provided on two opposite sides of the cover; the transparent pipe passes through the two openings of the two opposite sides of the cover.

9. The detection system of the state of charge of the flow battery as claimed in claim 8, further comprising a base, wherein the light source and the receiver are disposed on a top portion of the base; the cover is disposed on the top portion of the base and forms a receiving space with the top portion of the base; a part of the transparent pipe is disposed in the receiving space.

10. The detection system of the state of charge of the flow battery as claimed in claim 9, further comprising two first positioning members and two second positioning members, wherein a axis is defined; the transparent pipe extends along the axis; the two first positioning members are disposed on the top portion of the base; the light source and the receiver are disposed between the two first positioning members along the axis; the transparent pipe is disposed on a top portion of each of the two first positioning members; the two second positioning members are disposed between the two first positioning members along the axis; the two second positioning members are connected to the cover and a bottom of each of the two second positioning members abuts against an outer wall of the transparent pipe.

11. The detection system of the state of charge of the flow battery as claimed in claim 1, wherein the light source and the receiver are disposed in an outer portion of the transparent pipe.

12. The detection system of the state of charge of the flow battery as claimed in claim 1, wherein at least one of the the light source and the receiver is disposed in an inner portion of the transparent pipe.

13. The detection system of the state of charge of the flow battery as claimed in claim 1, wherein the receiver is disposed in an inner portion of the transparent pipe.

14. The detection system of the state of charge of the flow battery as claimed in claim 13, wherein the receiver is covered by a transparent and waterproof material.
